(19) United States
(12) Patent Application Publication
(10) Pub. No.: US 2004/0108524 A1
(43) Pub. Date: Jun. 10, 2004

(54) Semiconductor device and method of manufacturing the same

(75) Inventors: Masashi Kitazawa, Tokyo (JP); Takashi Kuroi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/453,590

(22) Filed: Jun. 4, 2003

(30) Foreign Application Priority Data
Dec. 9, 2002 (JP) P2002-356682

(51) Int. Cl. H01L 27/10

(52) U.S. Cl. 257/202

(57) ABSTRACT

In an isolation structure formed by filling an isolation film (2) in a trench (12) formed in the surface of a substrate (1), the isolation film (2) contains an impurity whose concentration decreases from the bottom portion to top portion of the isolation film (2).

### BACKGROUND OF THE INVENTION

1. Field of the Invention

The present invention relates to a semiconductor device and a method of manufacturing the same. For instance, it applies to a semiconductor device having an STI structure in which a trench is formed in a semiconductor substrate and is filled with an oxide film, and also applies to a method of manufacturing such semiconductor device.

2. Description of the Background Art

Generally, in a semiconductor device formed on a silicon substrate (hereinafter briefly referred to as substrate), an isolation structure is formed using a silicon oxide film in order to electrically isolating devices such as transistors.

In forming such isolation structure, the LOCOS (local oxidation of silicon) process for selectively oxidizing substrates is not suitable for size reduction of isolation films. Therefore, a method is currently employed for many fine devices in which a substrate is selectively etched to form trenches therein and the trenches are filled with an oxide film. An isolation structure formed by this method is called an STI (shallow trench isolation) structure.

However, the isolation structure needs to be formed more finely as device miniaturization progresses. Then, the width of a trench formed in a substrate during formation of the STI structure is further reduced, causing the aspect ratio of the trench to be further increased.

To fill such trench having an increased aspect ratio with an oxide film, a method using an HDP-CVD (high density plasma-chemical vapor deposition) system has conventionally been employed by which an oxide film is filled in a trench while adding an impurity of high reactivity such as fluorine to a source gas for CVD and while performing chemical etching (see e.g., Japanese Patent Application Laid-Open No. 10-12718 (1998) (FIG. 4)).

Since the impurity-containing oxide film obtained by the above method has reflow capability, gap-filling capability of the oxide film into the trench having an increased aspect ratio formed in the substrate is improved. Further, filling the impurity-containing oxide film into the trench formed in the substrate advantageously relieves physical stress between the STI structure and substrate.

To improve the gap-filling capability of the oxide film into a recent trench having an increased aspect ratio, the oxide film needs to contain some amount of impurity atoms of high concentration.

However, the STI structure including the oxide film formed by the above method uniformly contains an impurity of high concentration from its bottom portion to its surface. Thus, an oxidation process by heat treatment at high temperatures after forming the STI structure, for example, when depositing a gate insulation film, may result in out-diffusion of impurity atoms from the surface of the STI structure, causing the impurity atoms to be absorbed into the gate insulation film.

Once the impurity atoms are absorbed into the gate insulation film, the composition of the gate insulation film is changed, which degrades the electrical property of the gate insulation film.

Besides, the STI structure uniformly containing an impurity of high concentration gives rise to the following problem in process.

That is, the impurity-containing oxide film varies in the rate of wet etching using hydrofluoric acid, and hence, difficult to exercise shape control by the wet etching.

Accordingly, a two-layered STI structure has been proposed in which a first oxide film containing an impurity is formed as the lower layer and a second oxide film containing no impurity is stacked on the first oxide film as the upper layer (see e.g., Japanese Patent Application Laid-Open No. 2000-332099 (pp. 4-7, FIGS. 1-4)).

Such two-layered STI structure, in which the second oxide film contains no impurity, can prevent out-diffusion of impurity atoms from the surface of the STI structure.

However, to form such two-layered STI structure, first and second CVD steps and an etching step performed between the first and second CVD steps are required, which results in complexity of steps.

### SUMMARY OF THE INVENTION

It is therefore an object of the present invention to provide a semiconductor device having an STI structure formed by simple steps showing a good gap-filling capability of an oxide film which does not exert any adverse influence upon other materials due to out-diffusion of impurity atoms caused by a later heat treatment step, and also to provide a method of manufacturing such semiconductor device.

A first aspect of the present invention is directed to the semiconductor device having a trench isolation structure in which an isolation film is filled in a trench formed in a surface of a substrate. The isolation film contains an impurity whose concentration gradually decreases from the bottom portion to the top portion of the isolation film.

After the isolation structure is formed, out-diffusion of impurity atoms from the isolation film can be avoided even when heat treatment is performed, for example, for forming a gate insulation film, which can prevent impurity atoms from being absorbed into the gate insulation film. Hence, degradation of the gate insulation film in electrical property can be prevented. Further, the impurity concentration is lower at the top portion of the isolation film, which can avoid variations in the rate of wet etching using hydrofluoric acid or the like due to the presence of impurity. Thus, the isolation film can be brought into a correct form.

A second aspect of the present invention is directed to the semiconductor device having a trench isolation structure in which an isolation film is filled in a trench formed in a surface of a substrate. The isolation film contains an impurity whose concentration is uniform from the bottom portion to a predetermined depth and gradually decreases from the predetermined depth to the top portion of the isolation film.

The same effects can be obtained as in the first aspect.

A third aspect of the present invention is directed to the method of manufacturing a semiconductor device. The method includes the following steps (a) to (c). The step (a) is to form a trench in a surface of a substrate. The step (b) is to fill an isolation film containing an impurity in the trench. The step (c), after the step (b), is to reduce impurity concentration in the vicinity of the top of the isolation film.

The semiconductor device of the first aspect can be manufactured through simple steps.

A fourth aspect of the present invention is directed to the method of manufacturing a semiconductor device. The method includes the following steps (f) and (g). The step (f) is to form a trench in a surface of a substrate. The step (g) is to fill the trench with an isolation film containing an impurity, while varying a concentration of the impurity when added to a source gas.

The semiconductor device of the first aspect can be manufactured through simpler steps than in the third aspect by varying the concentration of added impurity in a final stage of the filling step so as to be lower than in an initial stage.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view illustrating an exemplary structure of a semiconductor device according to the present invention including an isolation film;

FIG. 2 illustrates a concentration distribution of an impurity contained in an isolation film according to a first preferred embodiment of the invention;

FIGS. 3A through 8 are sectional views illustrating manufacturing steps of the semiconductor device of the invention;

FIG. 9 is a sectional view illustrating the semiconductor device of the invention yet to be completed including the isolation film of final form;

FIG. 10 is a sectional view illustrating how a lower layer is formed in a trench;

FIG. 11 illustrates a concentration distribution of an impurity contained in an isolation film according to a second preferred embodiment of the present invention; and

FIG. 12 is a sectional view illustrating the yet-to-be-completed semiconductor device of the invention just after planarization is finished.

### DESCRIPTION OF THE PREFERRED EMBODIMENTS

Hereinafter, preferred embodiments of the present invention will specifically be described referring to the accompanying drawings.

### First Preferred Embodiment

FIG. 1 is a sectional view illustrating an exemplary structure of a semiconductor device according to the present invention.

In the semiconductor device shown in FIG. 1, an isolation film 2 of STI structure made of silicon oxide film and the like is formed in the surface of a substrate 1 such as silicon substrate in order to isolate active regions (not shown) formed by ion implantation. A gate electrode 3 is formed on the substrate 1, and an interlayer dielectric 4 is formed to cover the substrate 1 as well as the isolation film 2 and gate electrode 3. Further, contact plugs 5 are formed extending from the upper surface of the interlayer dielectric 4 to reach the substrate 1. Interconnect lines 6 are formed to come into contact with the upper surfaces of the contact plugs 5.

The gate electrode 3 includes a gate electrode portion 3a and a gate insulation film 3b. To form the interlayer dielectric 4 without any void generated due to a step difference between the gate electrode 3 and substrate 1 and that between the isolation film 2 and substrate 1, BPTEOS or the like obtained by doping boron, phosphorus and the like into, for example, an oxide film is used as a material of the interlayer dielectric 4.

The isolation film 2 according to the present embodiment filled in a trench formed in the surface of the substrate 1 has the following structure.

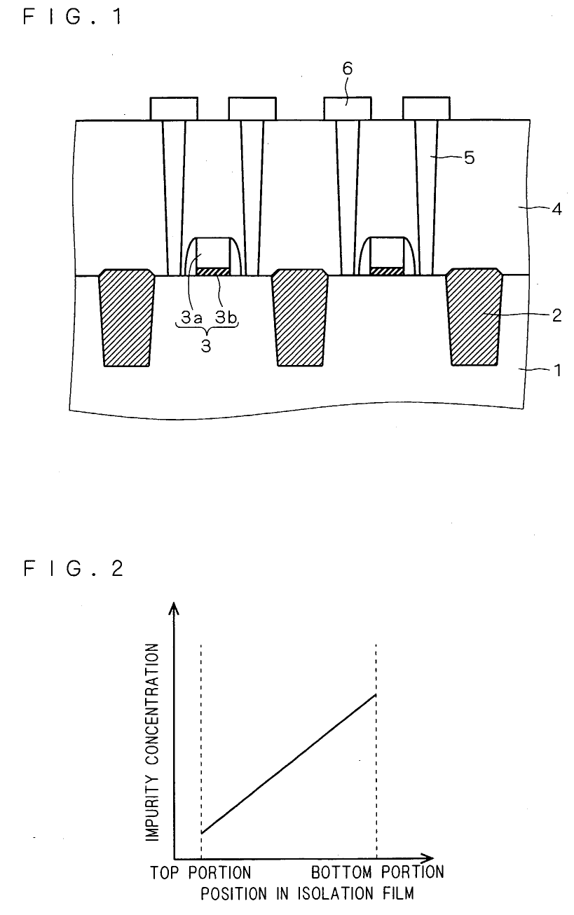

The isolation film 2 is made by adding an impurity selected from fluorine, boron, phosphorus, arsenic, chlorine, iodine and bromine, or combination of these impurities, to a silicon oxide film. The concentration of contained impurity increases toward the bottom portion and decreases toward the top portion of the isolation film 2. This is illustrated in FIG. 2.

That is, as is apparent from FIG. 2, the impurity concentration distribution gradually decreases from the bottom to top portion of the isolation film 2. For instance, the impurity concentration is about 1E19 cm⁻³ to 1E21 cm⁻³ near the bottom portion of the isolation film 2, and decreases toward the top portion of the isolation film 2 to reach a sufficiently low value of about 1E18 cm⁻³ or lower (in this case, not higher than about 10% of the impurity concentration at the bottom portion).

As described, the isolation film 2, containing an impurity such as fluorine, has the reflow capability, which can thus be improved in gap-filling capability into the trench formed in the substrate 1.

Further, since the concentration of impurity contained in the isolation film 2 is lower at the top portion than the bottom portion, out-diffusion of impurity atoms from the top portion of the isolation film 2 can be avoided from occurring due to heat treatment performed in forming the gate insulation film 3b, for example, in a later step, which can prevent diffused impurity atoms from being absorbed into the gate insulation film 3b. Thus, the gate insulation film 3b can be prevented from being degraded in electrical property.

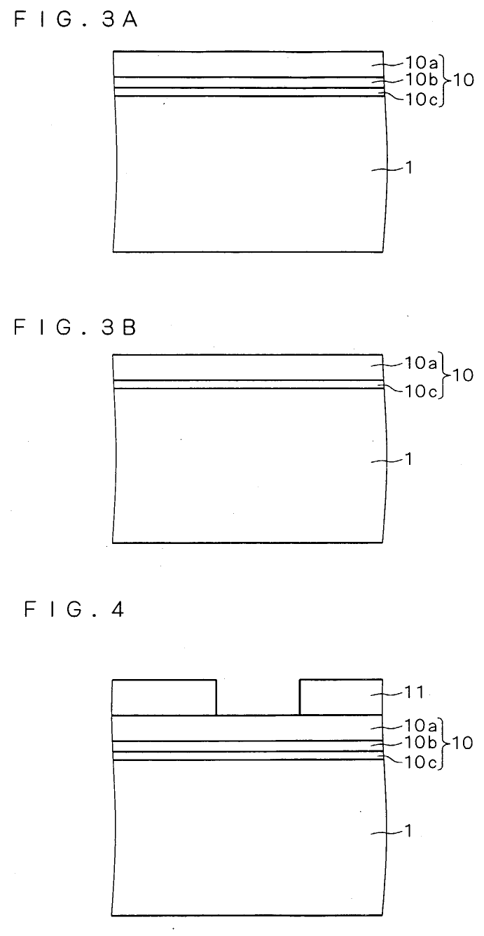

Next, an exemplary method of forming the isolation film 2 having the impurity concentration distribution shown in FIG. 2 will be specifically described referring to sectional views of FIGS. 3A through 9 illustrating the method of manufacturing the semiconductor device.

First, as shown in FIG. 3A, a hard mask 10 of layered structure is formed on the main surface of the substrate 1. The hard mask 10 has, for example, an oxide film 10c of about 5-30 nm thickness, a polysilicon film 10b of about 10-50 nm thickness and an uppermost silicon nitride film 10a of about 30-200 nm thickness being stacked in this order.

As another example of the hard mask 10 shown in FIG. 3B, a two-layered structure may be adopted in which an oxide film 10c of about 5-30 nm thickness and a silicon nitride film 10a of about 30-200 nm thickness are stacked in this order.

Next, a photoresist 11 is formed on the main surface of the hard mask 10 and is patterned by lithography into a predetermined form as shown in FIG. 4.

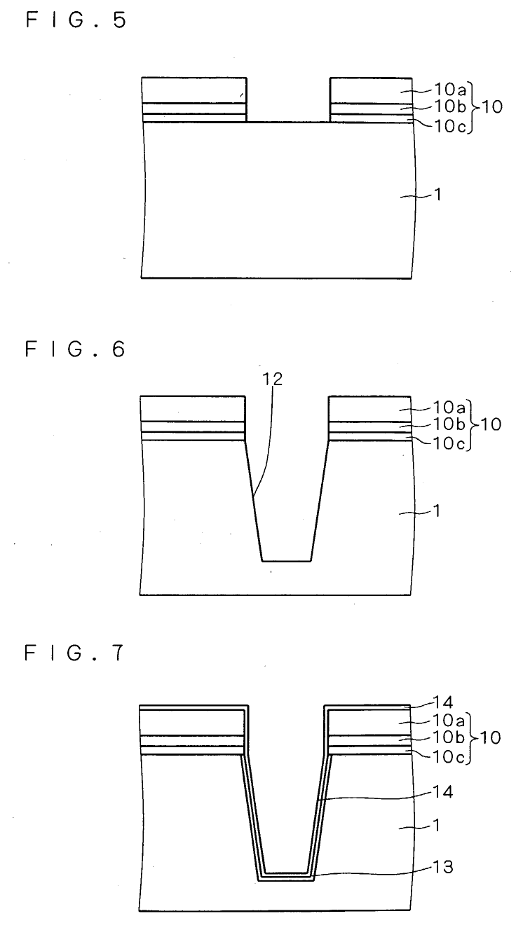

Next, after the hard mask 10 is etched using the patterned photoresist 11 as a mask, the photoresist 11 is removed to bring the hard mask 10 into a predetermined form as shown in FIG. 5.

Next, the substrate 1 is subjected to anisotropic etching using the hard mask 10 of the predetermined form as a mask, thereby forming a trench 12 as shown in FIG. 6. The trench 12 has a depth of, for example, about 150-500 nm and a thickness of, for example, about 50-200 nm.

Next, in order to remove damage inflicted upon the substrate 1 by the above-described anisotropic etching and to afford protection against plasma phenomenon to be caused by a HDP-CVD system in a later step, the trench 12 is subjected to heat treatment for depositing a thermal oxidation film 13 of, for example, about 5-30 nm thickness as shown in FIG. 7.

Further, in order to prevent impurity atoms contained in the isolation film 2 to be filled in the trench 12 in a later step from diffusing into the substrate 1, a stopper film 14 of, for example, about 5-20 nm thickness is formed on the surfaces of the thermal oxidation film 13 and hard mask 10 as shown in FIG. 7. The use of a silicon oxynitride film or silicon nitride film for the stopper film 14 can prevent impurity atoms from diffusing into the substrate 1.

In the case where the amount of impurity atoms diffusing into the substrate 1 is so small (for example, where the amount of heat treatment performed in a later step is so small) that the influence upon the electrical property of the substrate 1 is negligible, the stopper film 14 may be omitted.

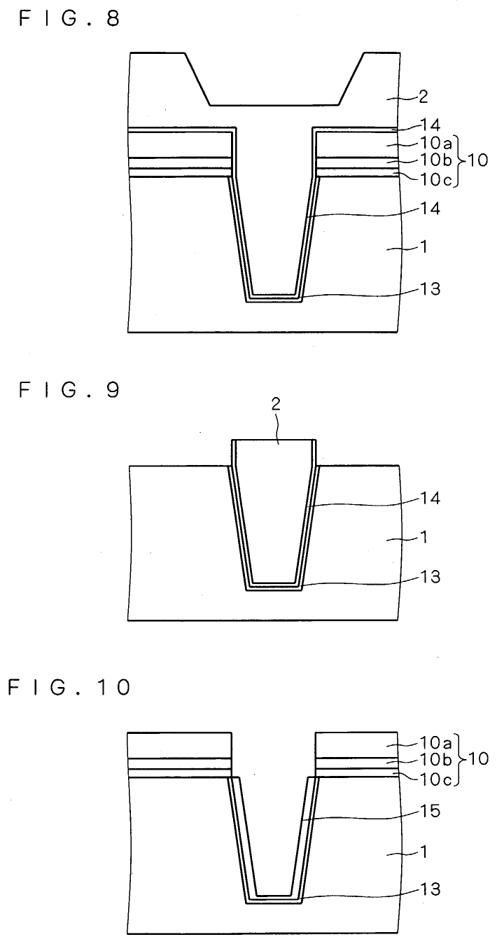

Next, as shown in FIG. 8, the isolation film 2 is filled in the trench 12 formed in the surface of the substrate 1 using a HDP-CVD system. An impurity of high reactivity such as fluorine is added to a source gas for CVD while filling the isolation film 2 in the trench 12. The concentration of added impurity is uniform throughout the filling step. The concentration of impurity contained in the isolation film 2 after the filling step is uniformly distributed at a value of, for example, about 1E19 cm⁻³ to 1E21 cm⁻³.

For an impurity to be added to the source gas for CVD, any of fluorine, boron, phosphorus, arsenic, chlorine, iodine and bromine, or combination of these impurities may be adopted.

Next, the impurity-containing isolation film 2 filled in the trench 12 is subjected to heat treatment. This heat treatment causes out-diffusion of impurity atoms from the top portion of the isolation film 2, which can reduce the impurity concentration near the top portion of the isolation film 2. Thus, the impurity concentration in the depth direction is distributed as shown in FIG. 2. That is, the impurity concentration at the top portion of the isolation film 2 is lower than that at the bottom portion.

The heat treatment is performed at, for example, about 1000-1100° C. for about 60-180 minutes.

Lastly, the semiconductor device shown in FIG. 8 already undergone the heat treatment for promoting out-diffusion of impurity atoms is subjected to planarization such as a general CMP (chemical vapor deposition) process. Thereafter, an appropriate step difference is made between the isolation film 2 and substrate 1 by wet etching using hydrofluoric acid or the like, thereby forming the isolation film 2 of final structure as shown in FIG. 9 in the substrate 1.

As described, filling the isolation film 2 in the trench 12 formed in the substrate 1 while adding an impurity of high reactivity such as fluorine to the source gas for CVD and while performing chemical etching can improve the gap-filling capability of the isolation film 2 into the trench 12. Further, since the isolation film 2, containing an impurity such as fluorine, has the reflow capability, the gap-filling capability can further be improved.

Furthermore, the heat treatment (specifically at 1000-1100° C.) is performed on the isolation film 2 particularly in order to cause impurity atoms contained in the isolation film 2 with a uniform concentration to diffuse from the isolation film 2. Accordingly, through simple steps, the impurity concentration at the top portion of the isolation film 2 can be reduced as compared to that at the bottom portion.

Therefore, further out-diffusion of impurity atoms from the isolation film 2 can be avoided even if heat treatment is performed after forming the isolation film 2, for example, when forming the gate insulation film 3b. This prevents impurity atoms from being absorbed into the gate insulation film 3b, and hence prevents degradation of the gate insulation film 3b in electrical property.

Further, by performing heat treatment for reducing the impurity concentration at the top portion of the isolation film 2 before wet etching to be performed for shaping the isolation film 2, variations in the rate of wet etching using hydrofluoric acid or the like can be avoided. Thus, the isolation film 2 can be brought into a correct form.

In order to achieve the above effects, it is preferable that the impurity concentration at the top portion of the isolation film 2 should be about 1E18 cm⁻³.

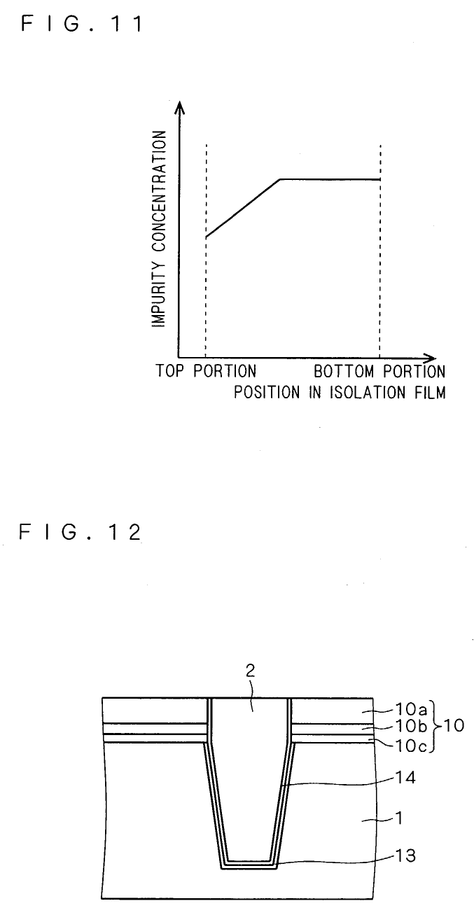

In the case of omitting the stopper film 14 as described above, an underlying film 15 of about 10-50 nm thickness made of the same material as the isolation film 2 except an impurity may be deposited as shown in FIG. 10 before filling the trench 12 with the impurity-containing isolation film 2, to thereby prevent reduction in physical adhesion between the impurity-containing isolation film 2 and substrate 1. This can prevent the isolation film 2 from being stripped from the substrate 1 due to stress and the like to be caused in a later step.

Even if the underlying film 15 contains an impurity of concentration lower than that at the bottom portion of the isolation film 2 (preferably, not higher than 10% of impurity concentration at the bottom portion) rather than containing no impurity as described above, the same effects can be expected.

Further, the thermal oxidation film 13, if formed thick in a thickness of about 20-50 nm, can also achieve the effect of the underlying film 15.

### Second Preferred Embodiment

An isolation film included in a semiconductor device according to the present embodiment, similarly to the first preferred embodiment, also contains an impurity selected from fluorine, boron, phosphorus, arsenic, chlorine, iodine and bromine, or combination of these impurities, and the impurity concentration increases toward the bottom portion and decreases toward the top portion of the isolation film. However, the concentration distribution differs in detail from that of the first preferred embodiment.

In this preferred embodiment, the isolation film contains an impurity in the depth direction with the concentration distribution shown in FIG. 11. That is, as is apparent from FIG. 11, the impurity concentration of the isolation film of the present embodiment is uniform from the bottom portion to a predetermined depth (for example, a position of about ⅓ to ⅔ of the isolation film) and decreases gradually from the predetermined depth to the top portion of the isolation film.

The method of forming the isolation film having such impurity concentration is almost the same as that of the first preferred embodiment but differs in the heat treatment performed particularly for promoting out-diffusion of impurity atoms from the top portion of the impurity-containing isolation film formed with a uniform concentration distribution (for example, about 1E19 cm⁻³ to 1E21 cm⁻³) after forming such isolation film in the trench.

In order to form the isolation film according to the present embodiment, heat treatment shall be performed at about 900-1000° C. for about 60-180 minutes.

Such heat treatment can promote out-diffusion of impurity atoms from the top portion of the insulation film, thereby forming the isolation film having the impurity concentration distribution as shown in FIG. 11. That is, the impurity concentration of the isolation film is almost uniform (about 1E19 cm⁻³ to 1E21 cm⁻³) from the bottom portion to a predetermined depth (for example, a position of about ⅓ to ⅔ of the isolation film) and gradually decreases from the predetermined depth to the top portion of the isolation film to reach a low value of about not higher than 1E18 cm⁻³ (in this case, not higher than about 10% of the impurity concentration at the bottom portion).

Adopting the isolation film having the above-described impurity concentration distribution, the following effects can be obtained in addition to those obtained in the first preferred embodiment.

That is, since an impurity of high concentration is uniformly contained in the isolation film 2 from the bottom portion to the predetermined depth, physical stress inflicted upon the substrate 1 by the isolation film 2 can be reduced, which can avoid an adverse influence such as reduction in currents which flow through devices such as transistors due to such physical stress.

Similarly to the first preferred embodiment, the structure may be employed in which the underlying film is deposited between the substrate and isolation film in the case where a stopper film is not formed in the trench.

### Third Preferred Embodiment

In the first preferred embodiment, the heat treatment is performed on the isolation film having a uniform impurity concentration for promoting out-diffusion of impurity atoms particularly for the purpose of forming the isolation film with the impurity concentration distribution as shown in FIG. 2. The present embodiment is intended to form the isolation film with the impurity concentration distribution as shown in FIG. 2 using another method.

The method of forming the isolation film according to the present embodiment includes the same steps up to forming a trench in a substrate and forming a thermal oxidation film and a stopper film (which may be omitted) in the trench as described in the first preferred embodiment, however, the method of forming the isolation film by a CVD step thereafter using a HDP-CVD system is different from that of the first preferred embodiment.

That is, when filling the trench formed in the surface of substrate with the isolation film, the impurity added to the source gas for CVD has a uniform concentration throughout the CVD step in the first preferred embodiment. In the present embodiment, however, the isolation film is formed using a source gas for CVD containing an impurity whose concentration is varied with time during the CVD step.

Specifically, in the filling step, according to the trend of variations in impurity concentration distribution shown in FIG. 2, the concentration of impurity added to the CVD source gas is high in an initial stage and gradually decreases toward a final stage.

As an impurity added to the source gas for CVD, any of fluorine, boron, phosphorus, arsenic, chlorine, iodine and bromine, or combination of these impurities are adopted, similarly to the first preferred embodiment.

Thereafter, planarization such as a general CMP process is performed, and thereafter, the appropriate step difference is made between the isolation film and substrate by wet etching using hydrofluoric acid or the like, thereby forming the isolation film of the structure shown in FIG. 9 in the substrate.

As described, particularly for the purpose of forming the isolation film having an impurity whose concentration is varied in the depth direction, heat treatment for promoting out-diffusion of impurity atoms can be omitted by adopting the method of the present embodiment, which allows reduction in the number of steps.

Heat treatment for promoting out-diffusion of impurity atoms may be performed after forming the isolation film by the CVD step according to the present embodiment. Although this increases the number of steps, the impurity concentration at the top portion of the isolation film can further be reduced.

### Fourth Preferred Embodiment

In the second preferred embodiment, particularly for the purpose of forming the isolation film to have the impurity concentration distribution as shown in FIG. 11, heat treatment is performed on the isolation film having a uniform impurity concentration for promoting out-diffusion of impurity atoms. The present embodiment is intended to form the isolation film having the impurity concentration distribution as shown in FIG. 11 using another method.

The method of forming the isolation film according to the present embodiment includes the same steps up to forming a trench in a substrate and forming a thermal oxidation film and a stopper film (which may be omitted) in the trench as described in the first preferred embodiment, however, the method of forming the isolation film by a CVD step thereafter using a HDP-CVD system is different from that of the first preferred embodiment.

That is, when filling the isolation film in the trench formed in the surface of the substrate, the impurity added to the source gas for CVD has a uniform concentration throughout the CVD step in the second preferred embodiment. However, in the present embodiment, the isolation film is formed using a source gas for CVD containing an impurity whose concentration is varied with time during the CVD step.

Specifically, in the filling step, according to the trend of variations in impurity concentration distribution shown in FIG. 11, the concentration of impurity added to the CVD source gas is maintained high from an initial stage to a middle stage (in which the isolation film is formed to a predetermined depth) and gradually decreases from the middle stage to a final stage.

As an impurity added to the source gas for CVD, any of fluorine, boron, phosphorus, arsenic, chlorine, iodine and bromine, or combination of these impurities are adopted, similarly to the first preferred embodiment.

Thereafter, planarization such as a general CMP process is performed, and then, the appropriate step difference is made between the isolation film and substrate by wet etching using hydrofluoric acid or the like, thereby forming the isolation film of the structure shown in FIG. 9 in the substrate.

As described, particularly for the purpose of forming the isolation film containing an impurity whose concentration is varied in the depth direction, heat treatment for promoting out-diffusion of impurity atoms can be omitted by adopting the method of the present embodiment, which allows reduction in the number of steps.

Heat treatment for promoting out-diffusion of impurity atoms may be performed after forming the isolation film by the CVD step according to the present embodiment. Although this increases the number of steps, the impurity concentration at the top portion of the isolation film can further be reduced.

### Fifth Preferred Embodiment

In the first and second preferred embodiments, heat treatment for promoting out-diffusion of impurity atoms particularly for the purpose of forming the isolation film having the impurity concentration distribution as shown in FIG. 2 or 11 is performed before planarization such as CMP.

In the present embodiment, however, the isolation film is subjected to heat treatment particularly for promoting out-diffusion of impurity atoms after planarization such as CMP.

The same steps are performed as in the first preferred embodiment up to filling of the isolation film 2 having a uniform impurity concentration distribution in the trench formed in the surface of the substrate 1 using a HDP-CVD system (FIG. 8).

Thereafter, planarization such as CMP is performed on the semiconductor device shown in FIG. 8 to form the semiconductor device yet to be completed as shown in FIG. 12. At this time, the isolation film 2 contains an impurity having a uniform concentration of, for example, about 1E19 cm⁻³ to 1E21 cm⁻³.

After the above-described planarization, the semiconductor device shown in FIG. 12 is subjected to heat treatment particularly for promoting out-diffusion of impurity atoms.

In the case of forming the isolation film 2 having the impurity concentration distribution shown in FIG. 2, heat treatment is performed at, for example, about 1000-1100° C. for about 60-180 minutes. Alternatively, in the case of forming the isolation film 2 having the impurity concentration distribution shown in FIG. 11, heat treatment is performed at, for example, about 900-1000° C. for about 60-180 minutes.

After the above-described heat treatment, lastly, the yet-to-be-completed semiconductor device shown in FIG. 12 is subjected to wet etching using hydrofluoric acid or the like to make an appropriate step difference between the isolation film 2 and substrate 1, thereby forming the isolation film 2 of the structure shown in FIG. 9 in the substrate 1.

With the methods of forming the isolation film 2 described in the first and second preferred embodiments, the heat treatment for promoting out-diffusion of impurity atoms is performed before planarization, so that part of the surface where the impurity concentration is lowest is polished and removed by the planarization.

Therefore, in the present embodiment, performing the heat treatment for out-diffusion of impurity atoms after polishing and removing an unnecessary portion of the isolation film 2 by planarization in advance can reduce the impurity concentration at the top portion of the isolation film 2 of final form as compared to that in the methods of the first and second embodiments.

Thus, further out-diffusion of impurity atoms from the isolation film 2 can further be avoided even when heat treatment is performed in forming a gate insulation film, for example, which can prevent impurity atoms from being absorbed into the gate insulation film. Hence, degradation of the gate insulation film 3b in electrical property can further be prevented.

### Sixth Preferred Embodiment

In the first and second preferred embodiments, heat treatment for promoting out-diffusion of impurity atoms particularly for the purpose of forming the isolation film having the impurity concentration distribution as shown in FIG. 2 or 11 is performed, and planarization such as CMP and wet etching using hydrofluoric acid are thereafter performed, thereby bringing the isolation film into final form.

However, in the present embodiment, after bringing the isolation film into final form (that is, after planarization such as CMP and wet etching using hydrofluoric acid or the like), the isolation film brought into final form is subjected to heat treatment particularly for promoting out-diffusion of impurity atoms.

Using a HDP-CVD system, the isolation film 2 having a uniform impurity concentration in the depth direction is filled in the trench 12 formed in the surface of the substrate 1, and thereafter, planarization such as CMP is performed on the isolation film 2, thereby forming the yet-to-be-completed semiconductor device shown in FIG. 12, similarly to the fifth preferred embodiment.

After the above-described heat treatment, the yet-to-be-completed semiconductor device shown in FIG. 12 is subjected to wet etching using hydrofluoric acid or the like to make an appropriate step difference between the isolation film 2 and substrate 1, thereby bringing the isolation film 2 into final form shown in FIG. 9 in the substrate 1. At this time, the isolation film 2 contains an impurity having a uniform concentration of about 1E19 cm⁻³ to 1E21 cm⁻³.

After bringing the isolation film 2 into final form, the semiconductor device shown in FIG. 9 is subjected to heat treatment particularly for promoting out-diffusion of contained impurity atoms.

In the case of forming the isolation film 2 having the impurity concentration distribution shown in FIG. 2, heat treatment is performed at, for example, about 1000-1100° C. for about 60-180 minutes, as described in the first preferred embodiment. Alternatively, in the case of forming the isolation film 2 having the impurity concentration distribution shown in FIG. 11, heat treatment is performed at, for example, about 900-1000° C. for about 60-180 minutes, as described in the second preferred embodiment.

Thereafter, a gate electrode and the like are formed.

With the method of forming the isolation film 2 described in the fifth preferred embodiment, heat treatment for promoting out-diffusion of impurity atoms is performed before bringing the isolation film 2 into final form by wet etching using hydrofluoric acid or the like. That is, part of the surface where the impurity concentration is lowest is removed by wet etching.

Therefore, in the present embodiment, performing heat treatment for promoting out-diffusion of impurity atoms after removing an unnecessary portion of the isolation film 2 by wet etching in advance can reduce the impurity concentration at the top portion of the finished isolation film 2 as compared to that in the method of the fifth embodiment.

Thus, as compared to the fifth preferred embodiment, out-diffusion of impurity atoms from the isolation film 2 can further be reduced even when heat treatment is performed in forming, for example, a gate insulation film, which can further prevent impurity atoms from being absorbed into the gate insulation film. Hence, degradation of the gate insulation film 3b in electrical property can further be prevented.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device having a trench isolation structure in which an isolation film is filled in a trench formed in a surface of a substrate, wherein
said isolation film contains an impurity whose concentration gradually decreases from the bottom portion to the top portion of said isolation film.

2. A semiconductor device having a trench isolation structure in which an isolation film is filled in a trench formed in a surface of a substrate, wherein
said isolation film contains an impurity whose concentration is uniform from the bottom portion to a predetermined depth and gradually decreases from said predetermined depth to the top portion of said isolation film.

3. The semiconductor device according to claim 1, wherein
said impurity concentration at the top portion of said isolation film is not higher than 1E18 cm⁻³.

4. The semiconductor device according to claim 2, wherein
said impurity concentration at the top portion of said isolation film is not higher than 1E18 cm⁻³.

5. The semiconductor device according to claim 1, wherein
said impurity is selected from the group consisting of fluorine, boron, phosphorus, arsenic, chlorine, iodine, bromine and combination of these impurities.

6. The semiconductor device according to claim 2, wherein
said impurity is selected from the group consisting of fluorine, boron, phosphorus, arsenic, chlorine, iodine, bromine and combination of these impurities.

7. The semiconductor device according to claim 1 further comprising, in said trench, an underlying film provided between said substrate and said isolation film, wherein
said underlying film is made of the same material as said isolation film and contains no impurity or an impurity whose impurity concentration is not higher than that at the bottom portion of said isolation film.

8. The semiconductor device according to claim 2 further comprising, in said trench, an underlying film provided between said substrate and said isolation film, wherein
said underlying film is made of the same material as said isolation film and contains no impurity or an impurity whose impurity concentration is not higher than that at the bottom portion of said isolation film.
